(19) United States
(12) Patent Application Publication
(10) Pub. No.: US 2026/0359688 A1
(43) Pub. Date: Nov. 12, 2026

(54) Hybrid Computing System for Quantum-Assisted Monte Carlo Simulation

(71) Applicant: HSBC Group Management Services Limited, London (GB)

(72) Inventors: Georgios KORPAS, London (GB); Philip INTALLURA, London (GB); Megan Charrisze GIRON, London (GB)

(73) Assignee: HSBC Group Management Services Limited, London (GB)

(21) Appl. No.: 18/587,078

(22) Filed: Feb. 26, 2024

(30) Foreign Application Priority Data
Mar. 20, 2023 (GB) 2304053.8

(51) Int. Cl. G06N 10/20; G06N 10/60

(52) U.S. Cl. CPC G06N 10/20; G06N 10/60

(57) ABSTRACT

A computer system for performing quantum-assisted Monte Carlo simulations is disclosed. The system comprises an interface adapted to communicate with a quantum computer; and a classical computing subsystem. The classical computing subsystem is arranged to control the quantum computer to perform a quantum amplitude amplification process on a quantum-encoded model of the simulated process, the process model comprising probability distributions of a plurality of input variables of the simulated process and being encoded on a quantum system comprising a set of qubits of the quantum computer. Based on measurements of the quantum system, the classical computer system obtains output statistics of the quantum amplitude amplification process and processes the output statistics using a polynomial optimisation algorithm to determine a simulation output, the simulation output comprising an estimate of an output parameter of the simulated process.

### FIELD OF THE INVENTION

The present application relates to a hybrid computing system for quantum-assisted Monte Carlo simulation and methods of performing such simulations.

### BACKGROUND OF THE INVENTION

Quantum computing promises to solve instances of certain problems currently intractable with (even high-performance) classical computers. The range of applications is vast, and includes applications in chemistry, pharmaceuticals, and financial services, among other domains.

Monte Carlo sampling is a set of techniques that randomly generate numerical quantities for the purpose of simulating a statistical distribution or computing a moment or other expectation thereof (e.g., mean, variance). It is used in many disciplines, including computational physics, artificial intelligence, various branches of engineering and computational finance.

Given the contemporary explosion in research and development in quantum computing, there has been recent interest in exploring quantum alternatives to classical Monte Carlo. The motivation for the search for quantum alternatives is rooted in the nature of these procedures, which are general and flexible enough to be effective for a wide array of possible real-life probability distributions but, in so doing, typically require a large quantity of samples to achieve good approximations. Current algorithms for complex applications therefore typically demand high-performance computing (HPC), or using a number of computing nodes in parallel to increase the number of samples while maintaining reasonable wall-clock times. However, HPC only partially mitigates the significant drawback of classical Monte Carlo, which can be expressed as slow mixing time. The mixing time can be thought of as a measure of how long it takes for the estimates to reach an acceptable distance from the theoretically desired quantity. In practical applications, apart from situations where simple distributions are in use, the procedure is known to mix slowly, requiring significant computing hours and thus time as well as energy expenditure.

Quantum alternatives to Monte Carlo can potentially achieve a significant performance advantage over the classical counterparts. This is because such tools have the potential to significantly improve the mixing time required. This could offer important benefits in various applications. In addition to lowering of computational expense, fast computations allow greater potential for real-time decision making based on simulation outcomes.

An existing quantum alternative to Monte Carlo is the Quantum Amplitude Estimation (QAE) algorithm. However, the complexity of this algorithm makes implementation on current and near-term quantum computers difficult or even impossible for many applications.

### SUMMARY OF THE INVENTION

Embodiments of the invention aim to provide alternative approaches to QAE to enable efficient implementation of quantum-assisted Monte Carlo simulations.

Aspects of the invention are set out in the independent claims. Certain preferred features are set out in the dependent claims.

Disclosed herein is a system for performing quantum-assisted Monte Carlo simulations, comprising:
an interface adapted to communicate with a quantum computer; and
a classical computing subsystem arranged to:
control the quantum computer to perform a quantum amplitude amplification process on a quantum-encoded model of a simulated process, the process model defining probability distributions of a plurality of input variables of the simulated process and being encoded on a quantum system comprising a set of qubits of the quantum computer;
obtain, based on measurements of the quantum system, output statistics of the quantum amplitude amplification process;
process the output statistics using a polynomial optimisation algorithm to determine a simulation output, the simulation output comprising an estimate of an output parameter of the simulated process; and
output the simulation output.

By using classically-implemented polynomial optimisation techniques (instead of a fully quantum implementation such as QAE), complexity of the quantum-implemented part of the system can be reduced significantly, enabling implementation on more limited quantum computers. Furthermore, polynomial optimisation techniques can provide valuable additional information on error bounds/optimality guarantees that is not available using some other approaches.

The term “classical computing subsystem” or similar preferably refers to any computer device or system implemented using conventional computer technology (e.g. based on semiconductor electronics and integrated circuits), rather than quantum computing.

Preferably the simulation output comprises an estimated expected value of a function defining the random process. The quantum-encoded model preferably encodes the function and the associated probability distribution of the input variables.

The classical computing subsystem is preferably configured to process the output statistics using the polynomial optimisation algorithm to compute a maximum likelihood value of the output parameter.

Preferably, the classical computing subsystem is configured to obtain, based on execution of the polynomial optimisation algorithm, error bounds and/or an optimality guarantee associated with the estimate of the output parameter, wherein the simulation output comprises the error bounds and/or optimality guarantee. This can provide valuable additional information on the accuracy of the parameter estimate produced by the simulation.

Preferably, the quantum amplitude amplification process comprises a plurality of passes of quantum amplitude amplification performed on the quantum system, the output statistics determined based on measurements obtained for the plurality of passes.

The classical computing subsystem preferably comprises a module implementing a semidefinite programming (SDP) or linear programming (LP) solver, the polynomial optimisation algorithm using the SDP or LP solver. The SDP/LP solver module comprises one or both of: a software SDP/LP solver module, and a hardware accelerator. In an example, the classical computing subsystem may comprise one or more host CPUs adapted to run software to perform control of the quantum computer and process output statistics of the amplitude amplification process using the polynomial optimisation algorithm, and the hardware accelerator is configured to support execution of the optimisation algorithm. The accelerator may comprise a graphics processing unit or other co-processor.

Preferably, the measurements relate to an amplitude of a state of the quantum system amplified by the quantum amplitude amplification process, the amplified state corresponding to the estimate of the output parameter.

The polynomial optimisation algorithm is preferably a trigonometric polynomial optimisation algorithm. Preferably, the polynomial optimisation algorithm optimises a likelihood function relating to a likelihood of the output parameter.

The system may be configured to determine the probability distributions based on statistical analysis of an input data set.

The quantum computer may be provided by a remote (e.g. cloud-based) quantum computing service or the computer system may include (or be locally connected to) the quantum computer.

Also disclosed is a method of performing quantum-assisted Monte Carlo simulations of a simulated process, comprising:
encoding a model of the simulated process on a quantum system comprising a set of qubits of a quantum computer, the model comprising a probability model defining probability distributions of a plurality of input variables of the simulated process;
performing quantum amplitude amplification on the quantum-encoded model;
obtaining, based on measurements of the quantum system, output statistics for multiple passes of the quantum amplitude amplification operation;
processing the output statistics using a polynomial optimisation algorithm to determine a simulation output, the simulation output comprising an estimate of an output parameter of the simulated process; and
outputting the simulation output.

The processing step preferably comprises processing the output statistics using a polynomial optimisation algorithm to compute a maximum likelihood value of the output parameter. The method may comprise obtaining, based on execution of the polynomial optimisation algorithm, error bounds and/or an optimality guarantee associated with the estimate of the output parameter, wherein the simulation output comprises the error bounds and/or optimality guarantee. The polynomial optimisation algorithm is preferably executed on a classical computer system.

The method in this example preferably further comprises performing one or more of the operations carried out by a system as set out above.

The disclosure also encompasses a computer program or computer-readable medium comprising software code adapted, when executed on a data processing system, to perform any method as set out herein or to implement a system as set out herein.

Features of one aspect or example may be applied to other aspects or examples, in any combination. For example, method features may be applied to system or computer program aspects or examples (and vice versa).

### BRIEF DESCRIPTION OF THE FIGURES

Certain embodiments of the invention will now be described by way of example only, in relation to the Figures, wherein:

FIG. 1 illustrates a system for performing quantum-assisted Monte Carlo simulation;

FIGS. 2A-2C illustrate alternative approaches to quantum-assisted Monte Carlo simulation;

FIG. 3 illustrates a quantum-assisted Monte Carlo simulation process;

FIG. 4 illustrates implementation of the quantum-assisted Monte Carlo simulation process using a hybrid computer system; and

FIG. 5 illustrates processing devices for implementing the hybrid computing system.

### DETAILED DESCRIPTION

Embodiments of the invention provide a hybrid classical/quantum computing system for implementing a variant of the Quantum Amplitude Estimation (QAE) algorithm. The hybrid system can be used to implement simulations analogous to Monte Carlo simulations and can maintain the speedup afforded by quantum implementation whilst replacing part of the quantum implementation with processing on a classical computer device, thereby making the process easier to implement on existing and near-term quantum computing technology.

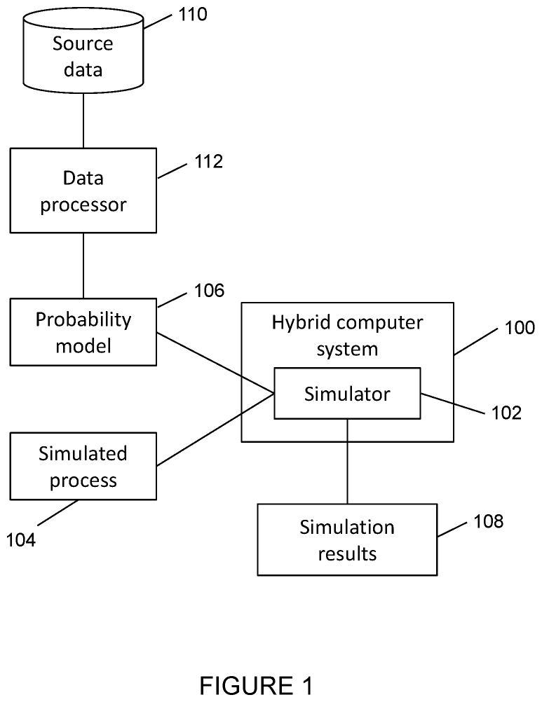

A system for implementing the described techniques is illustrated in FIG. 1.

The system includes a hybrid computer system 100, incorporating both classical and quantum computing devices. The hybrid computer system implements a simulator 102. The simulator implements a quantum-assisted Monte Carlo simulation, fulfilling a similar function to a fully classical Monte Carlo simulator or a fully quantum QAE implementation.

The simulator takes as input a specification of a simulated process 104 and a probability model 106 defining probability distributions for a number of input variables of the simulated process. The simulated process can be represented as a function ƒ(\vec{a}), where \vec{a} is a vector of the input variables and the output of the function is the parameter of interest. The probability model 106 defines probability distributions for those input variables. As an example, the input variables could define random photon energies and photon counts of photons incident on a photon detector cell that follow particular distributions and the simulation output (parameter of interest) could be the total photon energy incident on the cell over a time window.

In classical Monte Carlo simulation, the expectation value of the simulation output is obtained by randomly sampling the function ƒ using input samples with input values selected randomly according to their respective probability distributions:

$$S = \frac{1}{N} {\sum }_{i = 1}^{N} f ( {\vec{a}}_{i} ) \qquad ( 1 )$$

Here, \vec{a}ᵢ is a random input sample, N is the total number of samples, and S is the estimate of the expectation value of function ƒ. The estimate is obtained by averaging the result of evaluating ƒ for randomly sampled points; assuming sufficient samples, a reasonably close estimation of the expected value can be obtained.

In the present embodiments, the simulator employs a hybrid variant of Quantum Amplitude Estimation to generate an estimate of the expectation value, as described in more detail below.

The simulator generates simulation results 108 based on the simulation. These include the estimated expectation value of the output parameter of the simulation that is of interest and associated guarantees/error bounds as described in more detail later.

The probability distributions of the input variables (defined by probability model 106) are typically derived by statistical analysis from a dataset of real-world source data 110. However, probability distributions could alternatively be specified manually e.g. by a domain expert.

Quantum-assisted Monte Carlo estimates the sum S of the above equation using quantum amplitude estimation (QAE) techniques.

In particular, with Quantum-assisted Monte Carlo techniques, we are interested in evaluating integrals of the form:

Iₚ=∫_{[0,1]}_{ⁿ}p(\vec{x})ƒ(\vec{x})d\vec{x} (2)

for some arbitrary probability distribution p(\vec{x}). Using randomly sampled points {\vec{a}ᵢ} with \vec{a}ᵢ∈[0,1]ⁿ, the integral can be discretized into the sum:

$$a := {\sum }_{i = 0}^{N - 1} p ( {\vec{a}}_{i} ) f ( {\vec{a}}_{i} ) = {\sum }_{i = 0}^{N - 1} {p}_{i} {f}_{i} = 𝔼 [ f ( x ) ] \qquad ( 3 )$$

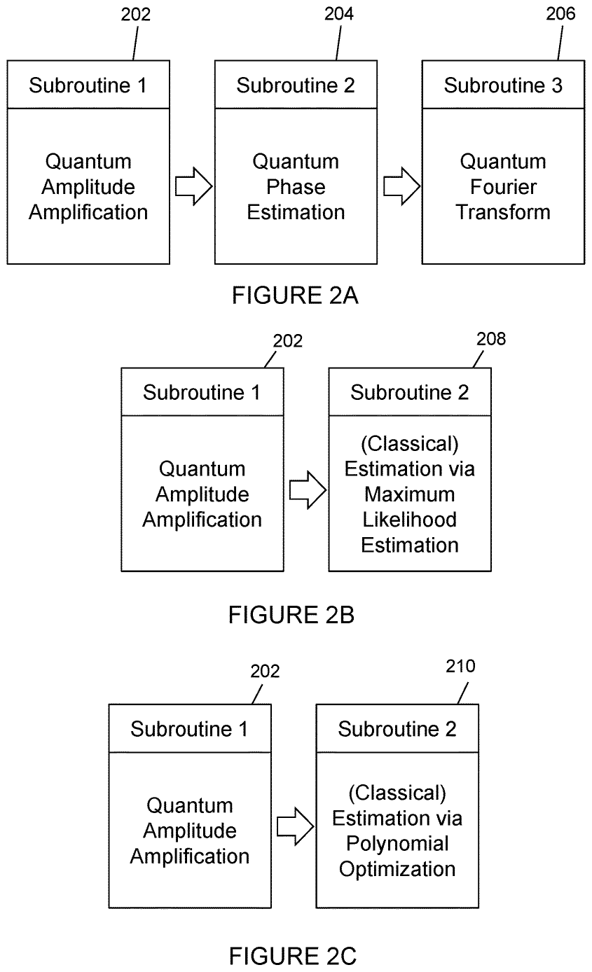

FIG. 2A illustrates the conventional Quantum Amplitude Estimation (QAE) algorithm in overview. QAE essentially starts by generalizing Grover's algorithm for arbitrary distributions, wherein it first amplifies the “right state” and then performs amplitude estimation for this state. As is shown, the QAE algorithm consists of three subroutines or modules. A first subroutine 202 performs quantum amplitude amplification (QAA) to amplify the “good” state corresponding to the integral being estimated. A second subroutine 204 implements quantum phase estimation to estimate the amplitude parameter. A third subroutine 206 performs a quantum Fourier transform (which prepares the quantum computer to be in a state where the result can be read out by repeated measurements). All three subroutines are implemented on a quantum computer, resulting in high complexity that makes practical implementation on current quantum computers challenging. The problem lies mainly in the quantum phase estimation subroutine, which is very costly to efficiently implement in NISQ (noisy intermediate-scale quantum) hardware.

An overview of Monte Carlo simulation and quantum-assisted Monte Carlo using QAE is provided in Philip Intallura et al. “A Survey of Quantum Alternatives to Randomized Algorithms: Monte Carlo Integration and Beyond”, arXiv:2303.04945v1 (March 2023), the entire contents of which are hereby incorporated by reference (with special reference to sections II and III.A providing background on Monte Carlo simulation and implementation of QAE as an alternative to classical Monte Carlo).

FIG. 2B depicts an alternative approach in which the second and third subroutines are replaced by a subroutine 208 for performing maximum likelihood estimation (MLE-QAE). However, MLE is a “heuristic” algorithm that cannot guarantee how good the estimation is. In many applications, guarantees on the optimality of the estimated solutions may be advantageous or even required. MLE-QAE is discussed in the document cited above.

FIG. 2C illustrates a hybrid approach according to embodiments of the present invention. The hybrid algorithm involves two subroutines. A first subroutine 202 performs quantum amplitude amplification (QAA) as in the previous examples. A second subroutine 210 then uses the output of the QAA step to perform the estimation using polynomial optimization techniques. The second subroutine is implemented using a software module running on a classical computer. Thus, in this approach, only the first subroutine, the QAA subroutine, is implemented on the quantum computer.

In this approach, QAA (subroutine 1) is performed according to the standard algorithm as used in conventional QAE. The details are thus known to those skilled in the art and are not repeated here, but see the above-referenced summary for details.

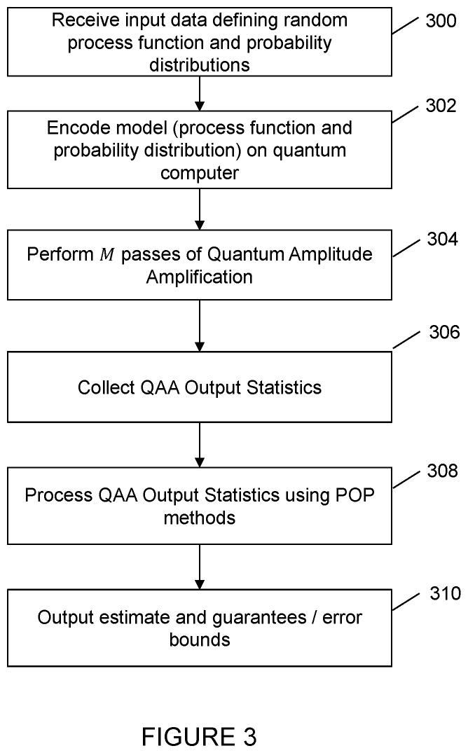

FIG. 3 illustrates a process for quantum-assisted Monte Carlo simulation using the hybrid algorithm.

In step 300, input data is received defining the probability model. This specifies a probability distribution for each of the input variables of the simulated process. The system also receives the definition of the function ƒ specifying the simulated process. The process function may be represented as a quantum circuit.

In step 302, the function ƒ and associated probability distribution are encoded on a system of qubits of a quantum computer. This involves encoding the classical probability distribution into a quantum state. Typically, amplitude encoding is used where the relevant information is stored in the amplitudes of quantum states. Any appropriate techniques can be used for encoding the function ƒ and associated probability distribution into a quantum state. In general, known encoding techniques can be used e.g. via qiskit (IBM®) or similar that will provide the quantum state.

In step 304, Quantum Amplitude Amplification (QAA) is performed. QAA serves to amplify the probability of measuring the state we are interested in. QAA is implemented by a quantum circuit that manipulates the encoded quantum state created in step 302.

Specifically, after loading the distribution of interest, QAA manipulates the quantum states such that they enhance the probability of measuring the expected value. This is done by first separating a specific state called the “good state” from the rest of the state (the “bad states”) using a projection operator and then boosting this projected state further away. This is repeated several times until the good state is almost orthogonal to the bad states. This results in the amplitude of the good state, and thus the probability of measuring it, being increased significantly. Standard known QAA implementations can be used to perform this step.

QAA is repeated a number of times, and QAA output statistics are collected in step 306.

These statistics comprise the amplitudes of the bad and the good states. The amplitude of the good state encodes the result of the integration we are interested in (see Eqn (2)).

In step 308, the QAA output statistics are processed using globally convergent polynomial optimization (POP) techniques. This step uses the statistics about the “good” amplitude measured in the previous step and aims to construct an empirical estimate of its actual value.

The optimization involves constructing a likelihood function or other relevant function as a function of the unknown amplitude parameter.

The likelihood function provides the objective function for the optimisation and may be based on the same objective function as used for MLE-QAE (see FIG. 2B and the Intallura et al. citation referenced above). However, unlike that approach, the likelihood function is expressed in the present system as a trigonometric polynomial. A detailed example of how a suitable objective function may be obtained for use in polynomial optimisation is given below.

In overview, polynomial optimization is performed to maximize the trigonometric polynomial representation of the likelihood function in order to obtain the maximum likelihood estimate of the parameter of interest (corresponding to the amplitude parameter). Trigonometric objective polynomial optimization methods are known to be able to provide guarantees of optimality of the solution and even achieve absolute convergence (due to the so-called convex relaxation methods that are employed).

Using the objective function in this form, the optimisation is performed using known (trigonometric) polynomial optimisation algorithms. This optimisation is implemented on a classical computer using specialised semidefinite programming (SDP) or linear programming (LP) solvers. Any appropriate known techniques may be used to implement the polynomial optimisation. For example, trigonometric sum-of-squares techniques as discussed in Bach et al. “Exponential convergence of sum-of-squares hierarchies for trigonometric polynomials”, arXiv:2211.04889v3, may be used.

The optimisation maximises the objective function resulting in estimation of the maximum likelihood amplitude parameter. The estimate corresponds to the integral associated with the input classical probability distribution as discussed above (and is interpreted as a Monte Carlo “path” or “simulation”).

The POP methods used can also provide strict error bounds/optimality guarantees. Furthermore, the optimisation can be continued until the error bounds are within a predetermined error tolerance threshold, allowing compute time to be traded for accuracy.

By way of background, in the context of optimization problems, a lower bound refers to a value that is less than or equal to the optimal value of the objective function for minimization problems or greater than or equal to the optimal value for maximization problems. Essentially, the lower bound serves as an estimate that indicates the lowest possible value the objective function can attain, given the constraints of the problem.

When using moment/Sums-of-Squares (SOS) relaxations for polynomial optimization problems (as is proposed for present embodiments), the lower bound is obtained by reformulating the original problem into a relaxation problem that is easier to solve. This relaxed problem can be represented as a semidefinite programming (SDP) problem, which can be solved using efficient algorithms. The optimal value of the SOS relaxation problem provides a lower bound for the original optimization problem.

However, the lower bound obtained from the moment/SOS relaxation might not necessarily coincide with the exact optimal value of the original problem. The gap between the lower bound and the true optimal value depends on the tightness of the relaxation. In some cases, the relaxation may be tight, meaning that the lower bound is equal to the true optimal value, while in other cases, the relaxation may be loose, resulting in a lower bound that is not as close to the true optimal value. Despite these limitations, lower bounds can provide valuable insights into the problem's structure, guide the development of heuristics or approximation algorithms, or serve as a starting point for other optimization methods. Also, they can help in assessing the quality of solutions obtained through other techniques by comparing the obtained solutions to the established lower bounds.

Thus, in the described approach, the POP optimization can output a bounded estimate. Bounds can additionally provide a guarantee of optimality in the sense that they indicated that the objective is bounded or, viewed another way, how far from the globally optimal solution the estimate may be (at most).

The results of the POP step are output in step 310, and include the estimate of the expectation value, and the associated bounds/optimality guarantees.

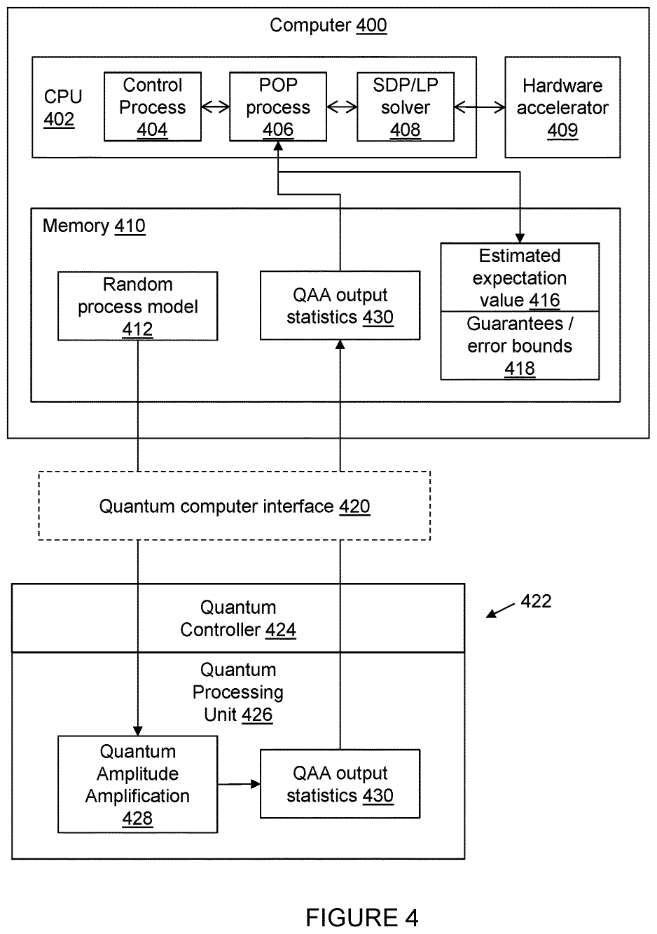

FIG. 4 illustrates the above process performed in a hybrid computer system including a conventional (classical) computer 400 and a quantum computing system 422.

The computer 400 in this example includes one or more host CPUs 402 running a control process 404 that controls overall execution of the hybrid quantum-assisted Monte Carlo algorithm. The control process supplies random process model 412 to the quantum computer system 422 via a quantum computer interface 420. The random process model includes the definition of the simulated process (function ƒ) and the probability distributions for the input variables.

The quantum computing system 422 comprises a quantum controller 424 and quantum processing unit 426. The quantum controller 424 transpiles quantum circuits into control signals which are applied to a set of qubits of the quantum processing unit 426 to execute the circuits. In the present case, a set of qubits of the quantum processing unit are configured to create a quantum state representing the function ƒ (defining the simulated process) and associated probability distributions. The quantum controller performs multiple passes of QAA, obtaining measurements of the quantum system for each pass. These repeated measurements form the QAA output statistics 430, which are transmitted back to the classical computer 400 where they are stored in memory.

Once the QAA output statistics 430 have been collected and transferred to computer 400. POP process 406 then executes the polynomial optimisation algorithm as a classical algorithm. This may involve use of specialised SDP or LP solver algorithms 408. Those algorithms may utilise a hardware accelerator 409, for example a graphic processing unit (GPU) or other co-processor of computer 400. Alternatively, the SDP/LP solver may be implemented fully in software or fully in hardware.

The POP process performs polynomial optimisation to maximise a likelihood function as discussed above, producing the estimate S of the expectation value (416) for the random process function ƒ. Additionally, the POP process produces a bounded guarantee on the estimate (418), which indicates the maximum possible error in the estimate (i.e. how far the estimate produced by the optimization could be, at most, from the optimal solution). The output data is stored in memory 410 and may be persisted to persistent storage and/or output to a user via suitable user interface as the simulation output.

The quantum computer interface 420 allows the computer 400 to submit quantum computations for execution by quantum computing system 422 and receive processing results. For example, the quantum computing system may be provided as a remote system, accessible via a cloud-based quantum computing service. Alternatively, the quantum computing system could be provided locally and connected via a local network connection or peripheral bus. In practice, depending on deployment, the quantum computer interface may include hardware and/or software components implemented within computer 400, within quantum computing system 422, and/or separately, e.g. as a cloud server managing access to a cloud-based quantum computing service.

The quantum computing system may include any quantum computer with a gate-based quantum processing unit that can implement Quantum Phase Amplification as a subroutine. Therefore, the described techniques can be used in a range of applications suitable for the currently available NISQ devices and future quantum devices. For example, the quantum computing system may be based on IBM Quantum Computers (such as Osprey) or a Rigetti Aspen M-2 system.

### Polynomial Optimisation—Implementation Details

In preferred embodiments, the optimisation uses the likelihood function employed in MLE-QAE (see FIG. 2B) as a starting point for deriving the objective function. The MLE-QAE approach is set out in Suzuki et al. “Amplitude Estimation without Phase Estimation”, Quantum Information Processing 19, 1 (2020) (arXiv:1904.10246v2).

In that approach, the probability to measure the good state is given by (see Suzuki et al. Section 3.1):

Lₖ(hₖ;θₐ)=[sin²((2mₖ+1)θₐ)]^{h}^{ₖ}[cos²((2mₖ+)θₐ]^{N}^{ₖ}^{-h}^{ₖ} (4)

where a is the parameter to be estimated, Nₖ is the number of measurements, hₖ is the number of measured “good” states, and mₖ is the number of Grover operator iterations. θₐ∈[0, π/2] is defined such that sin² θₐ=a. The state likelihood is then defined as:

$$L ( h ; {θ}_{a} ) = {\prod }_{k = 0}^{M} {L}_{k} ( {h}_{k} ; {θ}_{a} ) .$$

Then, Maximum-Likelihood-Estimation (MLE) is defined as the optimization problem:

$${\hat{θ}}_{a} = {argmax}_{{θ}_{a}} ( h ; {θ}_{a} ) = {argmax}_{{θ}_{a}} ln L ( h ; {θ}_{a} ) .$$

Firstly, note that Eq. (4) is non-negative since both the sine and cosine functions are squared. This can be written as a polynomial in the sense that if we view sin² and cos² as non-negative functions x and y respectively, we obtain a polynomial function

x^{h}^{ₖ}((2mₖ+1)θₐ)y^{N}^{ₖ}^{-h}^{ₖ}((2mₖ+1)θₐ)≡x^{h}^{ₖ}y^{N}^{ₖ}^{-h}^{ₖ}.

Since these terms are non-negative, one may require a sum-of-squares (SOS) constraint on them.

Returning to the original form, Eq. (4), this problem falls under the class of functions that are called “1-periodic continuous” and in our case it holds that Lₖ(hₖ; θₐ): [symbol] → [symbol] . Furthermore, this function has a finite Fourier norm

$${‖ L ‖}_{F} = {\sum }_{ω ∈ {ℤ}^{d}} \vert \hat{L} ( ω ) \vert$$

where \hat{L}(ω)= [symbol] L(x)e^{-2iπω}^{^{T}}^{x}dx is the Fourier series of ƒ. Such a function can then be represented as a sum of exponentials ƒ(x)=Σ_{w∈} [symbol] _{^{d}}\hat{ƒ}(ω)e^{2iπω}^{^{T}}^{x}, where the series is uniformly convergent.

To perform the optimization, the following steps are carried out:
1. We consider the Fourier transform of L.
2. For the given family of parameters mₖ, θₐ we check if

$${\hat{L}}_{k} ( - ω ) = {L}_{k}^{*} ( ω )$$

(where the latter is the complex conjugate).
3. If the above holds then the original L can be written as a trigonometric polynomial, that is a linear combination of monomials of sines and cosines. Let us denote the trigonometric polynomial representation of Lₖ as Trig(Lₖ)≡ [symbol] .
4. We apply moment/SoS relaxations to [symbol] −c (see Roh et al. “Interior-Point Algorithms for Sum-Of-Squares Optimization of Multidimensional Trigonometric Polynomials”, In: 2007 IEEE International Conference on Acoustics, Speech and Signal Processing-ICASSP '07, IEEE 2007), to obtain

$$0 \leq {inf}_{x ∈ ℝ} {ℒ}_{k} - {c}_{*} ( {ℒ}_{k} , S ) \leq ε ( {ℒ}_{k} , s ) ,$$

where c_{*}( [symbol] , s) is the optimal value with: c_{*}( [symbol] , s)≤inf [symbol] , providing this way the desired bound ε (see Bach et al., cited above).
5. If the above condition does not hold, that is if we cannot write Lₖ as a trigonometric polynomial, we modify our objective function as per Woodworth et al., “Non-convex optimization with certificates and fast rates through kernel sums of squares” (In: Conference on Learning Theory, PMLR, 2022, pp. 4620-4642):

c−∥Lₖ−c−g∥_{F},

where g is a trigonometric SoS polynomial of degree 2s and this is known to always yield a feasible solution.

Note that, unlike MLE, the method above presents a global optimization algorithm with convergence guarantees.

### Explicit Construction Example

Function Lₖ, with (2mₖ+1)=x is essentially [sin²(x)]^{m}[cos²(x)]ⁿ, with both m and n positive. To determine if this function can be written as a trigonometric polynomial, let's first use the double-angle identities for sine and cosine:

$${sin}^{2} ( x ) = \frac{1 - cos ( 2 x )}{2}$$

$${cos}^{2} ( x ) = \frac{1 + cos ( 2 x )}{2}$$

Now substitute these expressions into the original function:

$${{[ {sin}^{2} ( x ) ]}^{m} [ {cos}^{2} ( x ) ]}^{n} = {{[ \frac{1 - cos ( 2 x )}{2} ]}^{m} [ \frac{1 + cos ( 2 x )}{2} ]}^{n} .$$

As m and n are positive, the result will be a product of powers of the terms (1−cos(2x)) and (1+cos(2x)). Expanding these expressions using the binomial theorem, we get:

$${{[ \frac{1 - cos ( 2 x )}{2} ]}^{m} [ \frac{1 + cos ( 2 x )}{2} ]}^{n} = {\sum }_{j = 0}^{m + n} {c}_{j} {cos}^{j} ( 2 x ) ,$$

where cₖ are coefficients that depend on m and n. Therefore the given function can be expressed as a finite sum of terms, each of which is a product of a constant and a cosine function with a non-negative integer frequency. Therefore, the function [sin²(x)]^{m}[cos²(x)]ⁿ with both m and n positive is suitable to be written as a trigonometric polynomial.

### Example Processing Device

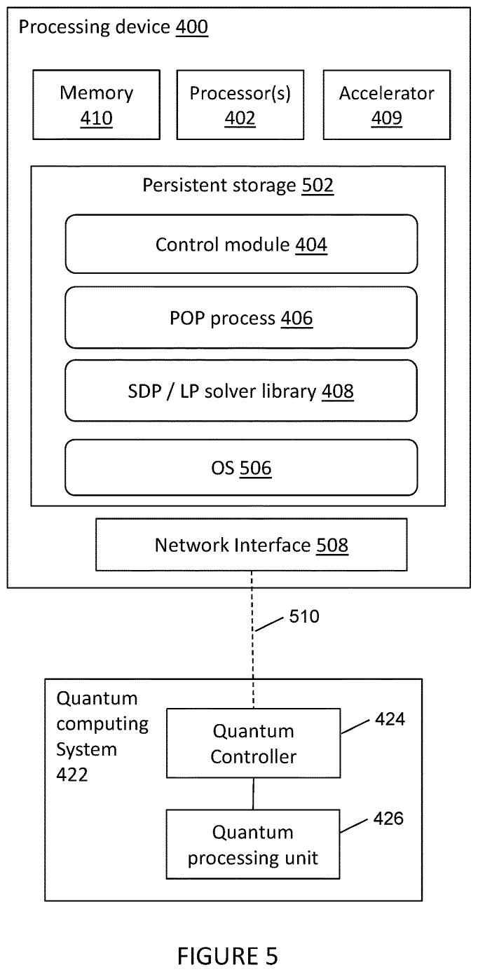

FIG. 5 illustrates a processing device for implementing the classical processing component of the hybrid computer system in accordance with an embodiment.

The processing device 400 may be based on conventional workstation or server hardware and as such includes one or more processors 402 together with volatile/random access memory 410 for storing temporary data and software code being executed (as shown in FIG. 4). As noted above, accelerator hardware 409 (e.g. a GPU) may be provided to provide hardware acceleration for the POP module.

A network interface 508 is provided for communication with other system components. For example, the processing device may communicate via the network interface with the external quantum computing system 422 (to run quantum circuits on the quantum processing unit 426 via the quantum controller 424). Communication may occur over one or more networks 510 (e.g. Local and/or Wide Area Networks, including private networks and/or public networks such as the Internet).

Persistent storage 502 (e.g. in the form of hard disk storage, optical storage and the like) persistently stores software and data for performing various described functions. In an example, this includes a simulator control module 404 for controlling the quantum-assisted Monte Carlo simulation, the POP process 406 implementing the polynomial optimisation algorithm and the SDP/LP solver library 408.

The persistent storage further includes a computer operating system 506 and any other software and data needed for operating the processing device. The device will include other conventional hardware components as known to those skilled in the art, and the components are interconnected by one or more data buses (e.g. a memory bus and I/O bus).

While a specific architecture is shown and described by way of example, any appropriate hardware/software architecture may be employed to implement the hybrid computer system.

Furthermore, functional components indicated as separate may be combined and vice versa. For example, the various functions may be performed by a single device 400 or may be distributed across multiple devices. As a concrete example, the SDP/LP solvers 408 could be implemented as a separate computing device, e.g. using general-purpose or specialised computing hardware.

As mentioned above, the described techniques can be used in place of classical Monte Carlo simulations in many different applications, including a wide range of engineering applications. The techniques are also suitable for use in computational finance applications, such as for the asset pricing of, e.g., stocks, bonds, futures, and other commodities, along with the risk management of portfolios comprising those assets. An advantage of the described algorithm is that it can output answers with a guaranteed error range that can be critical for certain applications within engineering or finance, whilst providing important speed ups compared to classical Monte Carlo simulations. For example, this technique can be used in order to speed up Monte Carlo simulations for option pricing or regulatory stress testing in near term NISQ devices with the advantage of providing strict error bounds and guarantees to optimality.

It will be understood that the present invention has been described above purely by way of example, and modification of detail can be made within the scope of the invention.

1. A computer system for performing quantum-assisted Monte Carlo simulations, comprising:
an interface adapted to communicate with a quantum computer; and
a classical computing subsystem arranged to:
control the quantum computer to perform a quantum amplitude amplification process on a quantum-encoded model of a simulated process, the process model defining probability distributions of a plurality of input variables of the simulated process and being encoded on a quantum system comprising a set of qubits of the quantum computer;
obtain, based on measurements of the quantum system, output statistics of the quantum amplitude amplification process;
process the output statistics using a polynomial optimisation algorithm to determine a simulation output, the simulation output comprising an estimate of an output parameter of the simulated process; and
output the simulation output.

2. A computer system according to claim 1, wherein the simulation output comprises an estimated expected value of a function defining a random process and wherein the quantum-encoded model encodes the function and the associated probability distribution of the input variables.

3. A computer system according to claim 1, wherein the classical computing subsystem is configured to process the output statistics using the polynomial optimisation algorithm to compute a maximum likelihood value of the output parameter.

4. A computer system according to claim 1, wherein the classical computing subsystem is configured to obtain, based on execution of the polynomial optimisation algorithm, error bounds and/or an optimality guarantee associated with the estimate of the output parameter, wherein the simulation output comprises the error bounds and/or optimality guarantee.

5. A computer system according to claim 1, wherein the quantum amplitude amplification process comprises a plurality of passes of quantum amplitude amplification performed on the quantum system, the output statistics determined based on measurements obtained for the plurality of passes.

6. A computer system according to claim 1, wherein the classical computing subsystem comprises a module implementing a semidefinite programming (SDP) or linear programming (LP) solver, the polynomial optimisation algorithm using the SDP or LP solver.

7. A computer system according to claim 6, wherein the SDP/LP solver module comprises one or both of: a software SDP/LP solver module, and a hardware accelerator.

8. A computer system according to claim 7, wherein the classical computing subsystem comprises one or more host CPUs adapted to run software to perform control of the quantum computer and process output statistics of the quantum amplitude amplification process using the polynomial optimisation algorithm, and the hardware accelerator configured to support execution of the optimisation algorithm.

9. A computer system according to claim 7, wherein the hardware accelerator comprises a graphics processing unit or other co-processor.

10. A computer system according to claim 1, wherein the measurements of the quantum system relate to an amplitude of a state of the quantum system amplified by the quantum amplitude amplification process, the amplified state corresponding to the estimate of the output parameter.

11. A computer system according to claim 1, wherein the polynomial optimisation algorithm is a trigonometric polynomial optimisation algorithm.

12. A computer system according to 1, configured to determine the probability distributions based on statistical analysis of an input data set.

13. A computer system according to claim 1, wherein the quantum computer is provided by a remote quantum computing service.

14. A computer system according to claim 1, further including the quantum computer.

15. A method of performing quantum-assisted Monte Carlo simulations of a simulated process, comprising:
encoding a model of the simulated process on a quantum system comprising a set of qubits of a quantum computer, the model comprising a probability model defining probability distributions of a plurality of input variables of the simulated process;
performing a quantum amplitude amplification operation on the quantum-encoded model;
obtaining, based on measurements of the quantum system, output statistics for multiple passes of the quantum amplitude amplification operation;
processing the output statistics using a polynomial optimisation algorithm to determine a simulation output, the simulation output comprising an estimate of an output parameter of the simulated process; and
outputting the simulation output.

16. A method according to claim 15, wherein processing the output statistics comprises processing the output statistics using a polynomial optimisation algorithm to compute a maximum likelihood value of the output parameter.

17. A method according to claim 15, comprising obtaining, based on execution of the polynomial optimisation algorithm, error bounds and/or an optimality guarantee associated with the estimate of the output parameter, wherein the simulation output comprises the error bounds and/or optimality guarantee.

18. A method according to claim 15, wherein the polynomial optimisation algorithm is executed on a classical computer system.

19. A method according to claim 15, further comprising performing the operations carried out by a system as claimed in claim 1.

20. A computer program or computer-readable medium comprising software code adapted, when executed on a data processing system, to perform a method as set out in claim 15.
